(19) United States
(12) Patent Application Publication
(10) Pub. No.: US 2012/0244461 A1
(43) Pub. Date: Sep. 27, 2012

(54) OVERLAY CONTROL METHOD AND A SEMICONDUCTOR MANUFACTURING METHOD AND APPARATUS EMPLOYING THE SAME

(75) Inventor: Satoshi Nagai, Albany, NY (US)

(73) Assignee: TOSHIBA AMERICA ELECTRONIC COMPONENTS, INC., Irvine, CA (US)

(21) Appl. No.: 13/071,956

(22) Filed: Mar. 25, 2011

(51) Int. Cl. G03F 7/20

(52) U.S. Cl. 430/30

(57) ABSTRACT

Overlay control methods, semiconductor manufacturing method and a semiconductor manufacturing apparatus are provided for restraining overlay error between lithography processes, of a semiconductor manufacturing process, within a tolerance of a semiconductor device. According to one or more aspects, enhanced overlay control mechanisms are provided to enable previous layers to perform corrections to an extent that does not exceed a correction ability of a next layer. For instance, the next layer can inform the previous layer of a tolerated range that is correctable so that the previous layer can perform corrections without exceeding the tolerate range. Accordingly, a feedback loop is established that extends across two exposure events and is not closed within a single exposure event as with conventional systems.

### FIELD

Embodiments described herein relate generally to an overlay control method that retrains overlay error within a correctable range.

### BACKGROUND

Silicon large-scale integrated circuits, among other device technologies, are increasing in use in order to provide support for the advanced information society of the future. An integrated circuit can be composed of a plurality of semiconductor devices, such as transistors or the like, which can be produced according to a variety of techniques. To continuously increase integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc. of resultant integrated circuits. However, as semiconductor device and device features have become smaller, conventional fabrication techniques have been limited in their ability to produce finely defined features.

By way of example, cost of process deviations or errors increases with shrinking feature sizes and increasing wafer sizes. An undetected or uncorrected error can be costly in terms of material waste. For instance, semiconductor devices are fabricated on wafers (e.g., made of silicon) by multiple process steps that create multiple overlaying layers of varying materials. The multiple overlaying layers can include semiconductor features designed to cooperate and interact with one another. Misalignment of the multiple overlaying layers, caused by process deviations, can result in semiconductor devices which are inoperable.

With lithographic processes, which image device patterns on wafers, overly control is utilized to detect and correct process deviations. Overlay relates to a measure of how well a new lithographic pattern has been imaged on top of an existing lithographic pattern on a wafer as measured at any point on the wafer. Overlay control, thereby, is a process by which an upper level image is aligned on top of a lower level image such that the two images are centered relative to one another.

With shrinking features sizes, overlay tolerances continue to reduce in kind. Similarly, next generation lithography techniques and equipment are being developed to fabricate the ever decreasing semiconductor features and devices. However, next generation lithography typically does not possess advanced overlay correction capabilities of existing photolithography equipment. Accordingly, it would be desirable to implement techniques for maintaining tight overlay control while enabling the introduction of next generation lithography into semiconductor device fabrication.

### BRIEF DESCRIPTION OF THE DRAWINGS

FIG. 1 is a block diagram of an exemplary semiconductor manufacturing system according to an embodiment of the subject innovation.

FIG. 2 is a block diagram of an exemplary semiconductor manufacturing system according to an embodiment of the subject innovation.

FIG. 3 is an illustration of a conventional overlay control technique in accordance with an example overlay model.

FIG. 4 is an illustration of an overlay model in accordance with an embodiment of the subject innovation.

FIG. 5 illustrates a flow of a conventional overlay control process.

FIG. 6 illustrates a flow of an overlay control process in accordance with one or more embodiments of the subject innovation.

FIG. 7 illustrates example results of a semiconductor manufacturing process employing a conventional overlay control process.

FIG. 8 illustrates example results of a semiconductor manufacturing processing employing an overlay control process according to one or more embodiments of the subject innovation.

FIG. 9 illustrates example results of a semiconductor manufacturing process employing a conventional overlay control process.

FIG. 10 illustrates example results of a semiconductor manufacturing processing employing an overlay control process according to one or more embodiments of the subject innovation.

FIG. 11 illustrates a flow of a conventional overlay control process.

FIG. 12 illustrates a flow of an overlay control process in accordance with one or more embodiments of the subject innovation.

FIG. 13 is a flow diagram of an example methodology for fabricating a semiconductor device with overlay control in accordance with an embodiment of the subject innovation.

FIG. 14 is a flow diagram of an example methodology for fabricating a semiconductor device with overlay control in accordance with an embodiment of the subject innovation.

### DETAILED DESCRIPTION

The subject innovation provides a mechanism for restraining overlay error between lithography processes, of a semiconductor manufacturing process, within a tolerance of a semiconductor device. Conventional overlay control mechanisms produce acceptable results when an exposure tool is capable of performing necessary corrections to adjust to distorted signatures of previous layers due to higher order intrafield corrections as well as process induced errors (e.g., caused when a wafer experiences extreme conditions such as high temperature annealing). However, when the exposure tool is incapable of performing the necessary conditions, the current wafer lot is discarded.

According to one or more embodiment of the subject innovation, enhanced overlay control mechanisms are provided to enable previous layers to perform corrections to an extent that does not exceed a correction ability of a next layer. For instance, the next layer can inform the previous layer of a tolerated range that is correctable so that the previous layer can perform corrections without exceeding the tolerated range. Accordingly, a feedback loop is established that extends across two exposure events and is not closed within a single exposure event as with conventional systems.

In a further embodiment, when corrections are to be made in an exposure event of the previous layer, so that later corrections, if necessary, are within the tolerated range of the next layer the previous layer applies corrections that are within a range to maintain a registration error between the previous layer and an immediate predecessor of the previous layer (e.g., the layer before the layer referred to as the previous layer) within a predetermined tolerance. However, when corrections to be applied by the previous layer introduce a registration error that exceeds the predetermined tolerance, the immediate predecessor of the previous layer also performs corrections so that corrections applied by the previous layer maintain a registration error within the predetermined tolerance.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

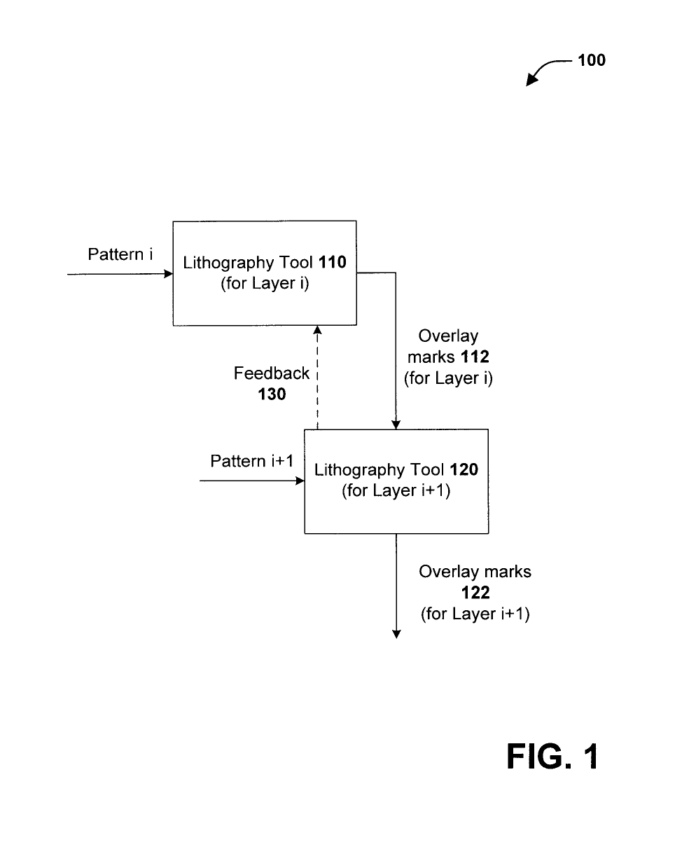

Referring first to FIG. 1, a semiconductor manufacturing system 100 is illustrated. As shown in FIG. 1, system 100 includes a lithography tool 110 and a lithography tool 120. According to an example, a lithography tool, such as lithography tools 110 and 120, can be machines, employed in wafer fabrication, configured to place a designed image or pattern on a wafer.

As depicted in FIG. 1, lithography tool 110 can be associated with Layer i of a wafer or semiconductor device being fabricated and lithography tool 120 can be associated with Layer i+1, e.g., a later or upper layer with respect to Layer i. To this end, lithography tool 110 can obtain Pattern i that specifies a design or layout of Layer i to be imaged by lithography tool 110. Similarly, lithography tool 120 receives Pattern i+1 specifying a design or layout of Layer i+1.

By way of example, lithography tool 110 exposes a substrate, covered with a resist, with light, wherein the light exposure is patterned according to Pattern i. Depending on the material of the resist, exposure can create a positive or a negative. With a positive resist, exposure causes a chemical change in the resist such that the portions of the resist layer exposed to light become soluble in a developer. With a negative resist, the chemical change induced by exposure renders the exposed portions of the resist layer insoluble to the developer. After exposure and develop, a layout according to Pattern i is laid out on the substrate. A subsequent processing step, such as an etching step or an ion implantation step, can be performed and controlled according to the layout. For instance, after exposure and develop, material on a lower layer not covered by the resist layer can be etched, thus transferring Pattern i to the material on the lower layer.

As discussed above in the Background, semiconductor devices are fabricated as multiple layers constructed on a wafer. For correct operation of the semiconductor devices, proper alignment of the various layers is important. Accordingly, for lithography tool 120 to image Pattern i+1 of Layer i+1, lithography tool 120 aligns to Layer i formed by lithography tool 110 based upon Pattern i.

To facilitate alignment, lithography tool 110 provides overlay marks 112 to lithography tool 120. Overlay marks 112, for Layer i, can be target patterns printed on the wafer to enable lithography tool 120 measure overlay between Pattern i as imaged by lithography tool 110 and Pattern i+1 as imaged by lithography 120. Based at least in part upon overlay marks 112, lithography tool 120 can identify overlay errors (also referred to as registration errors). To measure overlay and/or to identify overlay errors, lithography tool 120 can print Pattern i+1 onto the wafer and verify that the printed layer aligns to or is in registration with Pattern i of Layer i imaged by lithography 110. Particularly, lithography tool 120 can determine whether misalignment, e.g., alignment or registration error, is within a predetermined or preconfigured tolerance. If so, lithography tool 120 can conclude and later processing steps (not shown) can commence. To assist later processing steps with overlay, lithography tool 120 can provide overlay marks 122 associated with Layer i+1. However, when alignment or registration error exceeds tolerances, lithography tool 120 can attempt a correction. For instance, Layer i+1 can be removed and lithography tool 120 can re-execute imaging of Pattern i+1, while taking in account overlay measurements made on the previous attempt. Lithography tool 120, based on the overlay measurements for the previous attempt, can configure the exposure process to correct the errors. In another example, if the errors are beyond the tolerance correctable by lithography tool 120, the wafer being fabricated can be discarded and the overlay measurements can be employed to re-configure the tools for the next lot.

Conventionally, as described above, lithography tool 120 associated with an upper layer, e.g., Layer i+1, aligns to a lower layer, e.g., Layer i. Moreover, conventionally, lithography tool 120 includes overlay correction capabilities to adjust or revise the lithography process to account for detected overlay errors. According to an aspect of the subject innovation, lithography tool 120 can provide feedback 130 to lithography tool 110, which can be utilized for a next lot or a next wafer being fabricated by lithography tools 110 and 120. Based upon feedback 130, lithography tool 110 can pre-correct overlay errors as detected by lithography tool 120. In effect, lithography tool 110 aligns Layer i, e.g., the lower layer, to Layer i+1, the upper layer, rather than the inverse as with conventional overlay control.

Feedback 130 can include a variety of information. For example, feedback 130 can include overlay measurement, including registration errors, as measured by lithography tool 120. In addition, feedback 130 can include information regarding the correction capabilities of lithography tool 120. Based upon this information, lithography tool 110 can configure exposure parameters such that Pattern i is imaged to produce Layer i such that any resultant registration errors between Layer i and Layer i+1 are within the correction capabilities of lithography tool 120.

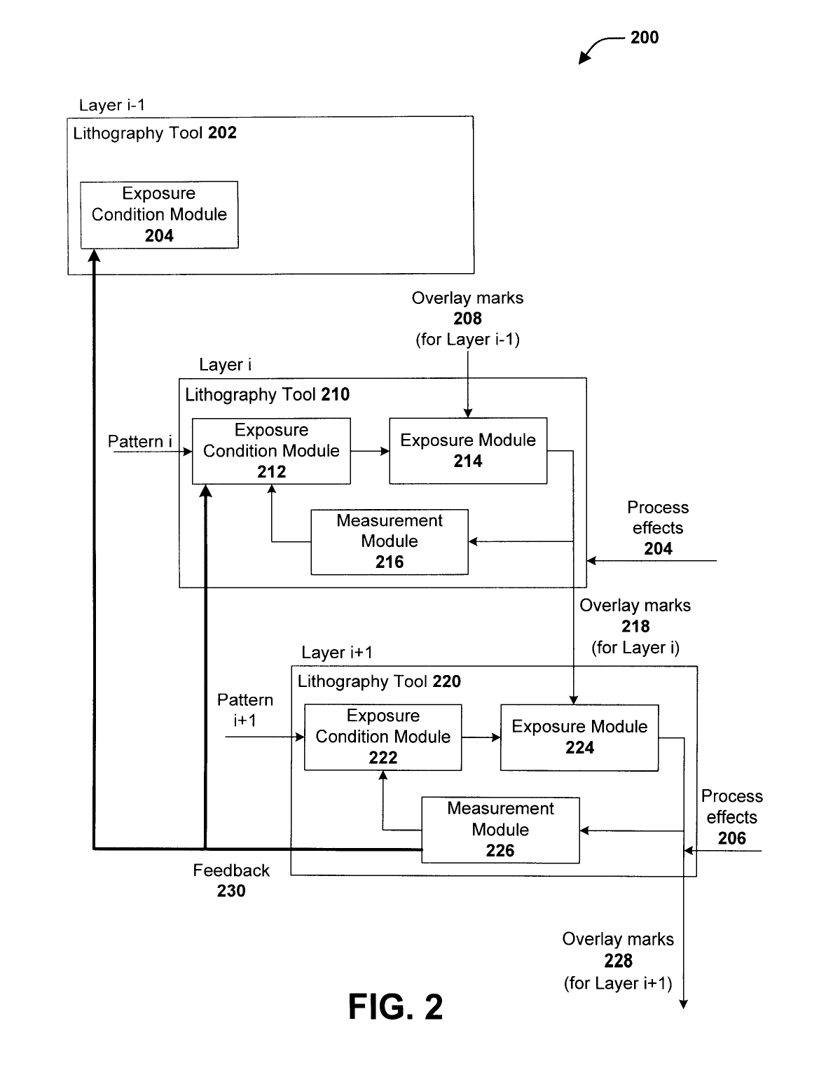

Turning to FIG. 2, illustrated is a semiconductor manufacturing system 200 that includes a lithography tool 210 corresponding to Layer i of a fabricated wafer and a lithography tool 220 corresponding to Layer i+1 of the wafer. Similar to lithography tools 110 and 120 described above, lithography tools 210 and 220 can obtain Pattern i and Pattern i+1, respectively, which specify a layout to be printed on the wafer to produce Layer i and Layer i+1, respectively.

As depicted in FIG. 2, lithography tool 210 can include an exposure condition module 212 configured to obtain Pattern i and generate exposure conditions and/or configuration parameters that establish and control an exposure process executed by lithography tool 210. In an example, exposure condition module 212 can provide the exposure conditions or configuration parameters to exposure module 214 configured to expose the wafer with light in accordance with Pattern i (e.g., print Pattern i on the wafer). Exposure module 214 can obtain overlay marks 208, associated with Layer i−1, from a previous layer. Exposure module 214 utilizes overlay marks 208 to align exposure of Pattern i to Layer i−1. After exposure, a measurement module 216, configured to provide metrology functionalities, determines overlay between Layer i−1 and Layer i as printed by exposure module 214. If overlay error exceeds tolerances (e.g., the amount of error increases risk of faults in the resultant semiconductor device), exposure condition module 212 can revise exposure conditions or configuration parameters to reduce overlay error as reported by measurement module 216. If overlay errors does not exceed tolerances, lithography tool 210 can conclude the lithography process associated with Layer i and forward overlay marks 218, corresponding to Layer i, to the next layer, e.g., Layer i+1. As shown in FIG. 2, overlay marks 218 can account for process effects 204 from a process (e.g., ion implantation, etching, etc.), subsequent to the lithography process, which transfers Pattern i printed on the wafer by lithography tool 210 to the material actually comprising Layer i.

The next layer, Layer i+1, can be associated with lithography tool 220 which, similar to lithography tool 210, can include an exposure condition module 222, an exposure module 224, and a measurement module 226. These sub-components of lithography tool 220 can implement the same internal feedback loop as described above with regard to lithography tool 210, relative to Pattern i+1 and overlay marks 218. In addition, lithography tool 220 can forward overlay marks 228 to an upper layer, wherein overlay marks 228 account for process effects 206 from a process associated with Layer i+1.

According to an embodiment, in addition to determining overlay between Layer i and Layer i+1, measurement module 226 can determine whether registration errors, as indicated in the calculated overlay, are correctable by lithography tool 220. If such errors are correctable, lithography tool 220 can render appropriate adjusts as described above. However, if such errors are not correctable, lithography tool 220 can provide feedback 230 to lithography tool 210, which can be employed by lithography tool 210 for a next wafer lot. Feedback 230 can indicate a measure of the overlay between Layer i and Layer i+1, registration errors, and/or correction capabilities of lithography tool 220. On a subsequent wafer lot, exposure condition module 212 of lithography tool 210 can revise exposure conditions or configuration parameters in accordance with feedback 230 such that imaged pattern of Layer i results in an overlay within a correctable range of lithography tool 220.

In a further embodiment, the revision, by lithography tool 210, of exposure conditions or configuration parameters, to be made such that the imaged pattern of Layer i results in an overlay correctable by lithography tool 220 introduces registration errors between Layer i and Layer i−1 that exceed a tolerance, lithography tool 220 can provide feedback 230 to lithography tool 210 and also lithography tool 202 associated with Layer i−1 as shown in FIG. 2. For instance, lithography tool 210 also has a registration error tolerance which is correctable relative to overlay between Layer i and Layer i−1 as measured by the measurement module 216. Monitoring the registration error between Layer i and Layer i−1 ensures lithography tool 210 stays within tolerance. When a correction to be made by lithography tool 210 exceeds the tolerance, exposure condition module 204 of lithography 202 revises exposure conditions or configuration parameters in accordance with feedback 230 (and feedback from lithography tool 210 (not shown)) to ensure corrections by lithography tool 210 remain within tolerance.

In another embodiment, measurement modules 216 and 226 can model overlay between its respective layer and a previous layer according to a 10 parameter model. The 10 parameter model includes a set of intrafield parameters and interfield parameters. Interfield parameters regard all exposure fields of a wafer and intrafield parameters relate to specific exposure fields. In other words, interfield parameters are wafer-related parameters and intrafield parameters are field-related parameters. Interfield parameters can include wafer expansion in an x-direction, wafer expansion in a y-direction, wafer translation in an x-direction, wafer translation in a y-direction, wafer rotation, and wafer non-orthogonality. Intrafield parameters can include field magnification, asymmetric field magnification, field rotation, and asymmetric field rotation. Each layer can correspond to specific values of the ten parameters according to overlay determined between the layer and a pattern on a previous layer. Corrections to these values can be made by a lithography tool to correct overlay errors.

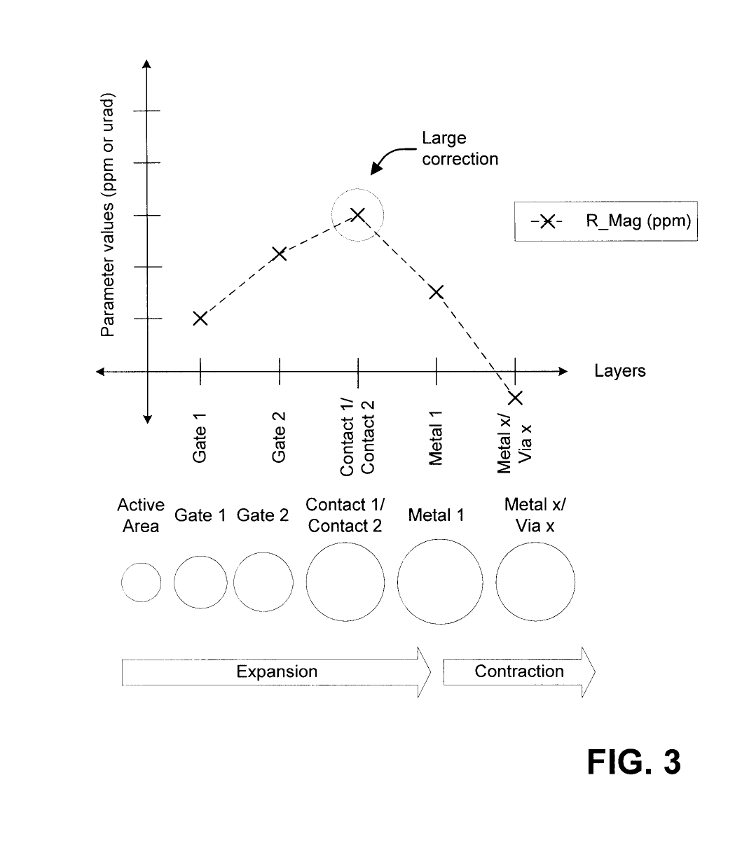

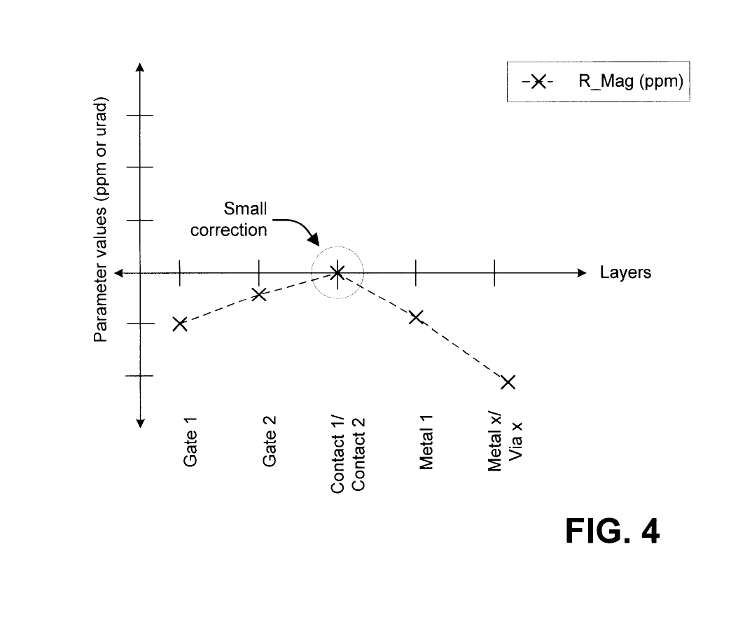

Turning to FIGS. 3 and 4, exemplary overlay models are illustrated. In accordance with these exemplary overlay models, a wafer comprising a plurality of layers is shown. For instance, the wafer can include a active area layer upon which a first gate layer is stacked. On the first gate layer is a second gate layer layer, followed by a first contact/second contact layer, then a first metal layer, and finally by one or more primary metal and interconnection (via) layers.

FIG. 3 illustrates a value for the field magnification (R_Mag) parameters of the 10 parameter model at each of a plurality of layers of a wafer. Field magnification relates to an expansion or contraction of an exposure field of the wafer as compared to a corresponding pattern of a previous layer. As shown in FIG. 3, the exposure field, from one layer to the next, goes through a period of expansion from the active area layer to the first metal layer, followed by a period of contraction from the first metal layer to the primary metal and via layers (MxNx) layers. In the period of expansion, the magnitude of expansion increases from one layer to the next up to a maximum at the first contact/second contact layer. After the first contact/second contact layer, while expansion still occurs, the relative increase in expansion is a smaller amount. As shown in FIG. 3, the first contact/second contact layer requires a large correction in field magnification.

To reduce the degree of correction performed by the first contact/second contact layer, previous layers can reduce an amount of compensation. For instance, as shown in FIG. 4, an amount of field magnification correction performed by the first gate and the second layers can be reduced in order to reduce an amount of correction performed by the first contact/second contact layer. In accordance with an example, fabrication equipment corresponding to the first contact/second contact layer can be incapable of the large correction needed, as shown in FIG. 3. Accordingly, the fabrication equipment can provide feedback information to other fabrication equipment associated with previous layers (e.g., first gate layer, second gate layer, etc.) specifying the amount of correction needed at the first contact/second contact layer and an extent of the correction capabilities of the equipment corresponding to the first contact/second contact layer. The equipment corresponding to the first gate layer and/or the second gate layer can, based upon the feedback information, compensate ahead of time (e.g., reduce field magnification), to reduce an amount of correction necessary at the first contact/second contact layer.

FIGS. 3 and 4 describe a general concept of an overlay correction scheme according to an embodiment of the subject innovation with respect to one parameter of the 10 parameter model. However, it is to be appreciated that the general concept, as described, can be extended to other parameters of the 10 parameter model or to other parameters of other overlay models.

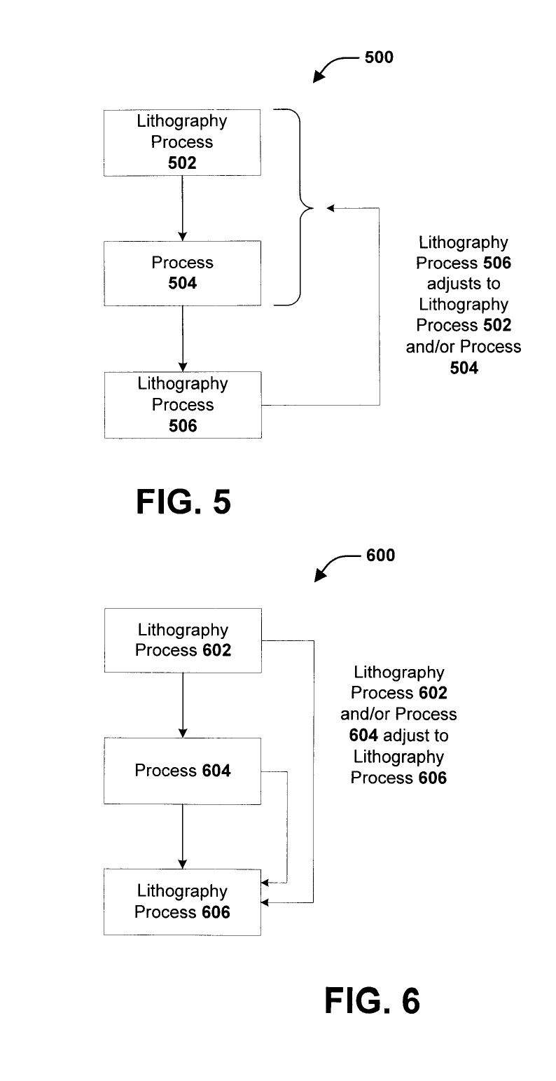

FIG. 5 illustrates a flow 500 of a conventional overlay control process. As shown in FIG. 5, a wafer, in a portion of a semiconductor manufacturing process, can progress through a lithography process 502 to a process 504 (e.g., an etching process, a ion implantation process, a lifting process, etc.), and finally to a lithography process 506. During execution of the lithography process 502 or the process 504, errors can be introduced which affects an overlay between a layer to be printed by lithography process 506 and a layer imaged previously by lithography process 502. In a conventional overlay control scheme, as shown in FIG. 5, lithography process 506 adjusts to lithography process 502 and/or process 504. In other words, in the conventional overlay control scheme, lithography process 506 makes appropriate correction to exposure conditions, wafer placement, etc., so that the pattern printed by lithography process 506 registers with the pattern incorrectly imaged by lithography process 502 or the pattern altered erroneously by process 504.

Turning to FIG. 6, illustrates is a flow 600 of an overlay control process in accordance with one or more embodiments. Similar to FIG. 5, FIG. 6 shows a portion of a semiconductor manufacturing process in which a wafer progresses through a lithography process 602 to a process 604 (e.g., an etching process, a ion implantation process, a lifting process, etc.), and finally to a lithography process 606. As mentioned above, during execution of the lithography process 602 or the process 604, errors can be introduced which affects an overlay between a layer to be printed by lithography process 606 and a layer imaged previously by lithography process 602. In a conventional overlay control scheme, later layers adjust to patterns created by lower layers. According to an embodiment, lower layers adjust to patterns that will be printed by upper layers. For instance, lithography process 602 and/or process 604 adjust to lithography process 606. In other words, lithography process 602 pre-corrects overlay errors induced by process 604, relative to a pattern to be printed by lithography process 606. In another example, process 604 can correct overlay errors introduced by lithography process 602 erroneously imaging the previous pattern on which lithography process 606 aligns a higher pattern. Accordingly, lithography process 606 is relieved of the burden of overlay correction.

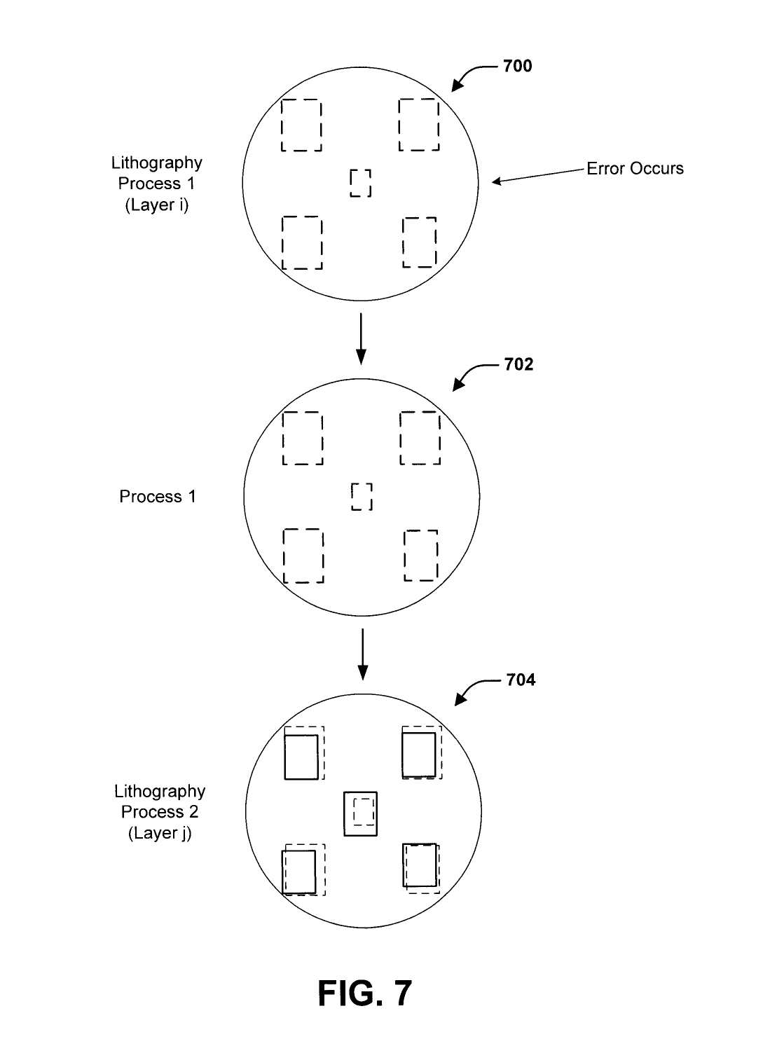

FIG. 7 illustrates example results of a semiconductor manufacturing process employing a conventional overlay control process. At 700, a portion or field of a wafer is depicted after execution of lithography process 1 in which pattern corresponding to layer i is printed. During execution of lithography process 1, an error occurs resulting in a malformed pattern as shown at 700 in FIG. 7. After lithography process 1, the wafer moves to process 1, which can be an etching process, a lift-off process, an ion implantation process, etc., associated with layer i or another layer. In the example depicted in FIG. 7, process 1 operates in accordance with the pattern printed by lithography process 1. Accordingly, at 702, the portion of the wafer shows that no change occurs in the pattern and the error persists. At 704, a result on the wafer after execution of lithography process 2 corresponding to layer j is illustrated. As shown at 704, features of the pattern formed by lithography process 1 are indicated with dashed lines while features of the pattern printed by lithography process 2 are indicated by the solid, bolded lines. As illustrated at 704, the pattern corresponding to lithography process 2 is misaligned relative to the pattern corresponding to lithography process 1. Thus, the overlay between layer j and layer i indicate extensive registration or overlay errors which requires advanced overlay correction by lithography process 2 under the conventional overlay control process.

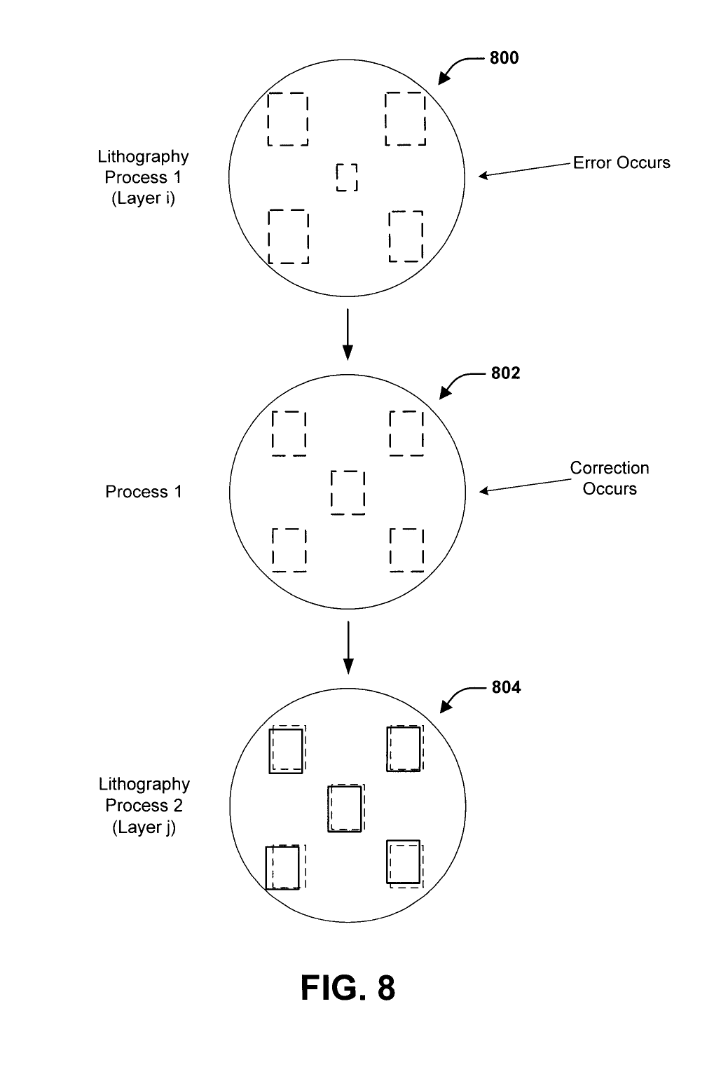

Turning to FIG. 8, illustrated is an example semiconductor manufacturing process employing an overlay control process according to one or more embodiments. FIG. 8 illustrates a similar semiconductor manufacturing process as FIG. 7 described above. However, according to an embodiment of the subject innovation, later layers, e.g., lithography process 2 of layer j, provide feedback to previous layers, e.g., layer i, and corresponding processes, e.g., lithography process 1 and process 1. Based upon the feedback, corrections of overlay errors between layer i and layer j can be performed prior to exposure by lithography process 2. For example, as shown in FIG. 8, parameters of process 1 can be adjusted to correct the errors introduced in the pattern corresponding to layer i by lithography process 1. At 800, an erroneous pattern printed by lithography process 1 is depicted. At 802, a resultant pattern on the wafer is illustrated after adjustment during execution of process 1. At 804, a result on the wafer after lithography process 2 prints a new pattern (layer j) on the previous pattern (layer i). As shown in FIG. 8, the overlay between layer i and layer j indicate minor overlay errors which can be easily corrected by lithography process 2.

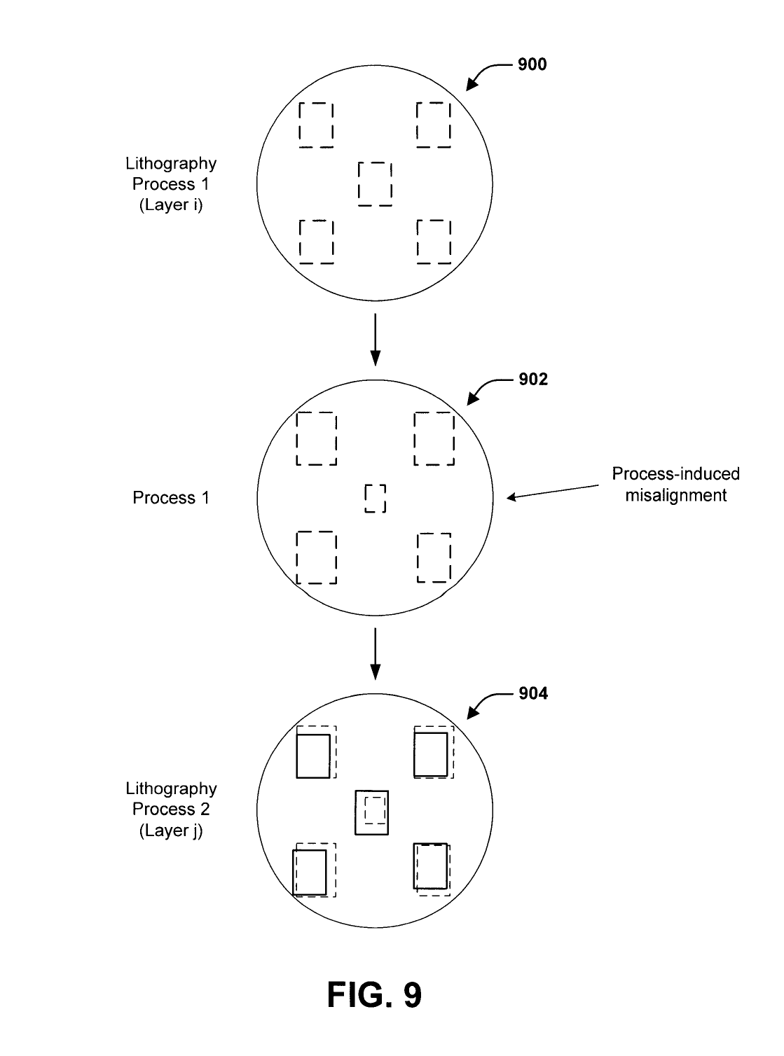

FIG. 9 illustrates example results of a semiconductor manufacturing process employing a conventional overlay control process. At 900, a portion or field of a wafer is depicted after execution of lithography process 1 in which pattern corresponding to layer i is printed. After lithography process 1, the wafer moves to process 1, which can be an etching process, a lift-off process, an ion implantation process, etc., associated with layer i or another layer. In the example depicted in FIG. 9, process 1 operates in accordance with the pattern printed by lithography process 1. As shown in FIG. 9, process-induced misalignment is introduced as a result of execution of process 1. Accordingly, at 902, the portion of the wafer shows that malformed pattern for layer i results. At 904, a result on the wafer after execution of lithography process 2 corresponding to layer j is illustrated. As shown at 904, features of the pattern formed by lithography process 1 and altered by process 1 are indicated with dashed lines while features of the pattern printed by lithography process 2 are indicated by the solid, bolded lines. As illustrated at 904, the pattern corresponding to lithography process 2 is misaligned relative to the pattern corresponding to lithography process 1 and erroneously altered by process 1. Thus, the overlay between layer j and layer i indicate extensive registration or overlay errors which requires advanced overlay correction by lithography process 2 under the conventional overlay control process.

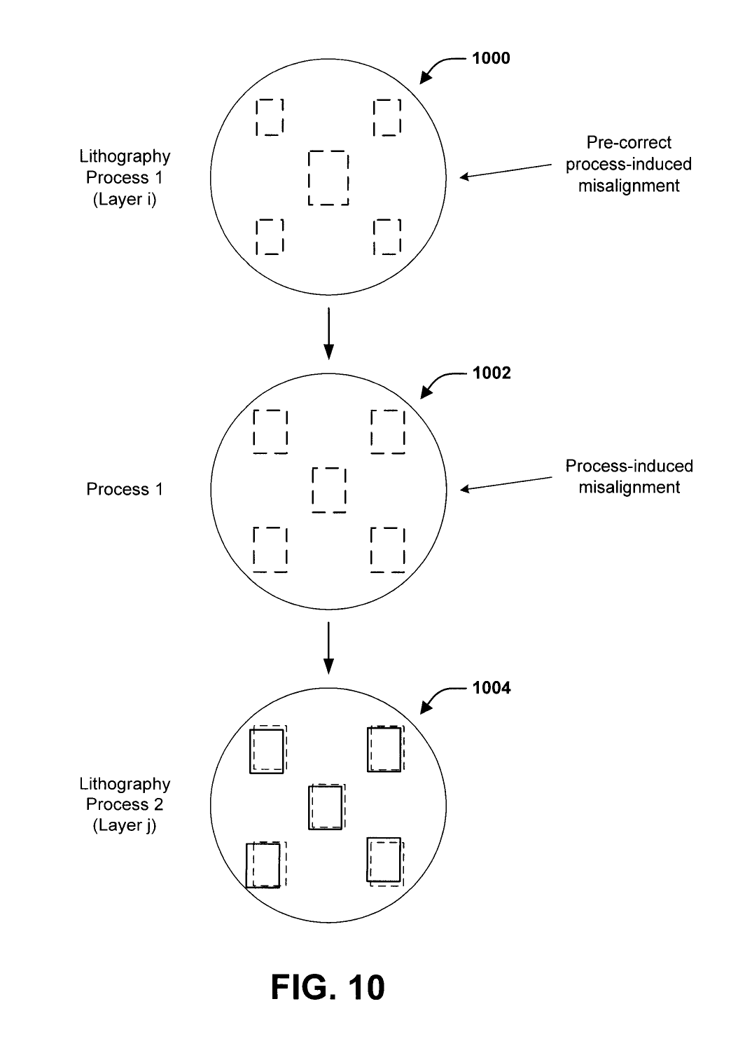

Turning to FIG. 10, illustrated is an example semiconductor manufacturing process employing an overlay control process according to one or more embodiments. FIG. 10 illustrates a similar semiconductor manufacturing process as FIG. 9 described above. However, according to an embodiment of the subject innovation, later layers, e.g., lithography process 2 of layer j, provide feedback to previous layers, e.g., layer i, and corresponding processes, e.g., lithography process 1 and process 1. Based upon the feedback, corrections of overlay errors between layer i and layer j can be performed prior to exposure by lithography process 2. For example, as shown in FIG. 10, lithography process 1 can pre-correct the process-induced misalignment generated by process 1. Accordingly, at 1000, an altered pattern printed by lithography process 1 is depicted. The altered pattern is based upon exposure conditions derived in part from the feedback from lithography process 2. In an aspect, the altered pattern compensates for errors of process 1 such that, as shown at 1002, a resultant pattern after execution of process 1 more closely resembles the correct pattern as originally intended by lithography process 1 (See FIG. 9). At 1004, a result on the wafer after lithography process 2 prints a new pattern (layer j) on the previous pattern (layer i). As shown in FIG. 10, the overlay between layer i and layer j indicate minor overlay errors which can be easily corrected by lithography process 2.

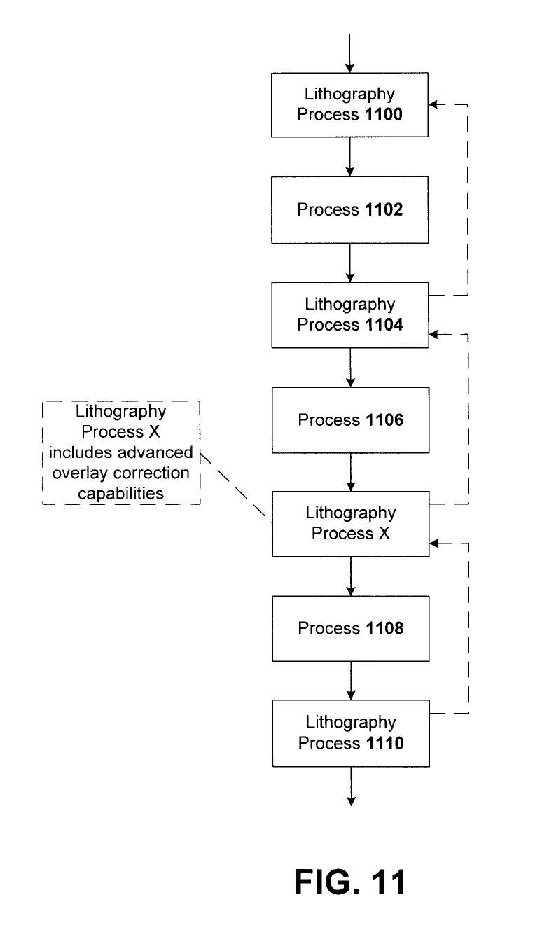

FIG. 11 illustrates a flow of a conventional overlay control process with regard to a portion of an example semiconductor manufacturing process. According to the example, semiconductor manufacturing process, a wafer progresses through a series of process step each configured to pattern or create layers which stack to form a semiconductor device. For example, as illustrated in FIG. 11, a wafer can go through lithography process 1100 which prints a first pattern corresponding to a first layer of the wafer. Subsequently process 1102 executes on the wafer. Process 1102 can be an etching process, an ion implantation process, a lift-off process, etc. performed on the first layer. After process 1102, a lithography process 1104 executes which images a second pattern corresponding to a second layer of the wafer. As part of lithography process 1104, an overlay between the first layer and second layer is determined and/or modeled. The overlay indicates how the second pattern aligns to or registers with the first pattern. Inconsistencies in alignment or registration can be referred to as overlay errors or registration errors. As shown by the dashed line in FIG. 11, in conventional overlay control, lithography process 1104, being the later process corresponding to the upper layer, adjusts the second pattern to align with the first pattern, as printed by lithography process 1100. In a similar fashion as that described above, the wafer can be subjected to process 1106 operating on the second layer, lithography process X which prints a third pattern on a third layer, process 1108 modifying the third layer, and lithography process 1110 which prints a fourth pattern on a fourth layer. As more and more layers are stacked, overlay errors can compound under the conventional scheme such that overlay between later layers, e.g., overlay between the third layer and the second layer, can require larger and larger corrections. Accordingly, lithography process X, under conventional overlay control where a layer adjusts to previous or earlier layers, advanced overlay correction capabilities are implemented.

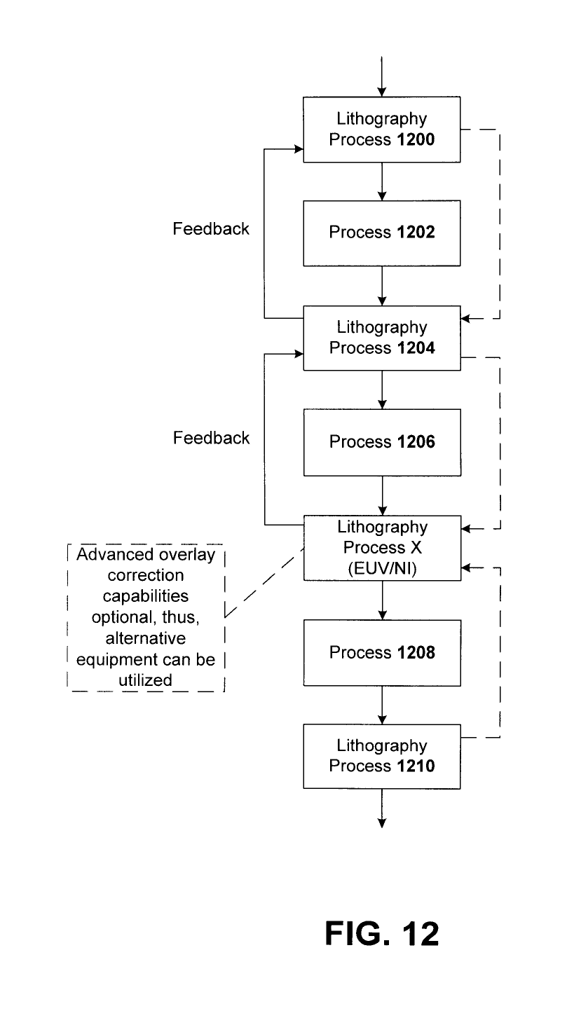

FIG. 12 illustrates a flow of an overlay control process in accordance with one or more embodiments of the subject innovation. According to the example, semiconductor manufacturing process, a wafer progresses through a series of process step each configured to pattern or create layers which stack to form a semiconductor device. For example, as illustrated in FIG. 12, a wafer can go through lithography process 1200 which prints a first pattern corresponding to a first layer of the wafer. Subsequently process 1202 executes on the wafer. Process 1202 can be an etching process, an ion implantation process, a lift-off process, etc. performed on the first layer. After process 1202, a lithography process 1204 executes which images a second pattern corresponding to a second layer of the wafer. As part of lithography process 1204, an overlay between the first layer and second layer is determined and/or modeled. The overlay indicates how the second pattern aligns to or registers with the first pattern. Inconsistencies in alignment or registration can be referred to as overlay errors or registration errors. As shown by the solid line in FIG. 12, in accordance with an embodiment, lithography process 1204, being the later process corresponding to the upper layer, can provide feedback regarding overlay correction capabilities as well as measured overlay between the second layer and the first layer. In a subsequent wafer lot, lithography process 1200 can utilize the feedback to adjust the lithographic process to pre-correct overlay errors detected by lithography process 1204 (shown in FIG. 12 as a dashed line). In a similar fashion as that described above, the wafer can be subjected to process 1206 operating on the second layer, lithography process X which prints a third pattern on a third layer, process 1208 modifying the third layer, and lithography process 1210 which prints a fourth pattern on a fourth layer.

Similar to lithography process 1200, lithography process 1204 can obtain feedback from a later or upper layer, such as the third layer printed by lithography process X. Lithography process 1204 can utilize the feedback to adjust the lithographic process forming the second pattern to better align with the third pattern to be printed by lithography process X. Since earlier layers pre-adjust respective patterns to later patterns, advanced overlay correction capabilities are optional. As such, alternative equipment, which is typically poor at overlay correction, can be utilized. For instance, next-generation lithography equipment, such as extreme ultraviolet (EUV) lithography equipment and nanoimprint (NI) lithography equipment, can fabricate nanometer scale patterns associated with ever shrinking semiconductor device scales. However, such next-generation lithography equipment has reduced overlay correction capabilities.

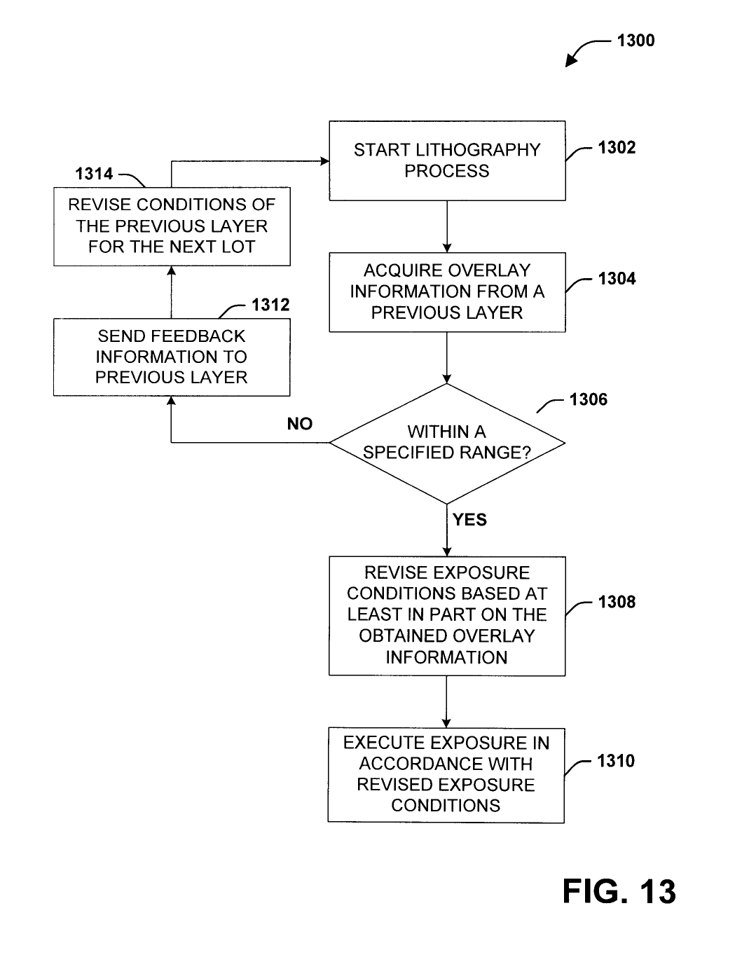

FIG. 13 is a flow diagram of an example method 1300 for fabricating a semiconductor device with overlay control in accordance with an embodiment of the subject innovation. At 1302, a lithography process executes an exposure to create a new pattern corresponding to a new layer. At 1304, overlay information is acquired relative to a previous pattern corresponding to a lower layer. At 1306, a determination is made, based upon the overlay information, as to whether or not correction of overlay errors is possible. If, at 1306, it is determined that correction is possible, method 1300 proceeds to 1308 where exposure conditions are revised based at least in upon the obtained overlay information. At 1310, an exposure is executed in accordance with the revised exposure conditions. According to an example, re-execution can include removing the new pattern already formed, reapplying a resist, and re-exposing the reapplied resist.

If, at 1306, it is determined that correction is beyond the tolerance, method 1300 process to 1312 where feed information is sent to the previous layer. The feedback information can include the overlay information acquired at 1304 as well as correction capabilities of the lithography process. At 1314, conditions of the previous layer can be revised and employed for a next wafer lot. In an example, the conditions of the previous layer are revised based upon the feedback information and the new conditions pre-correct overlay errors such that the overlay between the new pattern and the previous pattern fall within a correctable range of the lithography process.

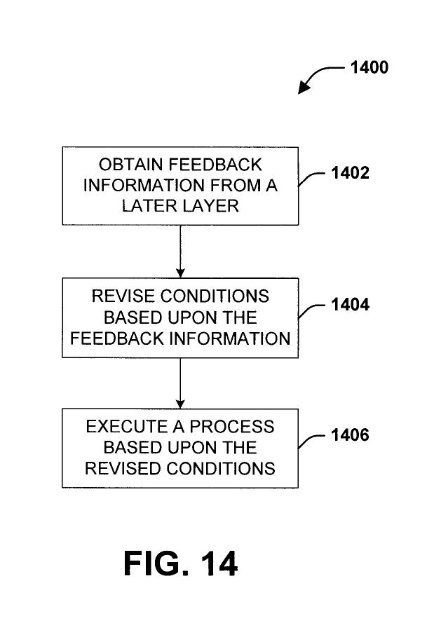

FIG. 14 is a flow diagram of an example method 1400 for fabricating a semiconductor device with overlay control in accordance with an embodiment of the subject innovation. At 1402, feedback information is obtained from a later layer. At 1404, conditions of a current later are revised based upon the feedback information. At 1406, a process is executed based upon the revised conditions.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. An overlay control method, comprising:
measuring, at a second layer, misalignment between a first pattern of a first layer on a substrate and a second pattern of the second layer on the substrate, wherein the first layer is a lower layer relative to the second layer; and
providing feedback information from the second layer to the first layer, wherein the feedback information includes information on the measured misalignment and information regarding a tolerance associated with the second layer, the tolerance indicates an extent of misalignment correctable at the second layer.

2. The overlay control method of claim 1, further comprising:
determining, based upon the measured misalignment, whether an error between the first pattern and the second pattern is correctable at the second layer; and
adjusting a process condition associated with the second layer to correct the error when the error is correctable.

3. The overlay control method of claim 2, further comprising:
executing a process configured to print the second pattern of the second layer on the substrate in accordance with the adjusted process condition.

4. The overlay control method of claim 2, wherein the determining whether the error is correctable at the second layer further comprises:
calculating a value of the process condition which corrects the error; and
determining whether the value is within a specified range.

5. The overlay control method of claim 1, further comprising:
transferring, via lithography equipment, the second pattern to the second layer of the substrate.

6. The overlay control method of claim 5, wherein the lithography equipment is at least one of extreme ultraviolet lithography equipment or nanoimprint lithography equipment.

7. The overlay control method of claim 1, further comprising:
obtaining the feedback information at the first layer;
revising a process condition of a process associated with the first layer; and
executing the process in accordance with the revised process condition.

8. The overlay control method of claim 7, further comprising:
determining whether executing the process in accordance with the revised process condition exceeds an acceptable range of a registration error measured between the first layer and a third layer which is a lower layer relative to the second layer; and
providing the feedback information to the third layer, wherein the third layer revises process conditions associated with the third layer and executes processes in accordance with the revised processes to maintain the registration error measured between the first layer and the third layer within the acceptable range.

9. The overlay control method of claim 7, wherein the process is a lithography process.

10. The overlay control method of claim 9, wherein the process condition pre-corrects process-induced misalignment introduced by a second process that executes after the lithography process associated with the first layer but before a process associated with the second layer.

11. The overlay control method of claim 7, wherein the process is at least one of an etching process, a deposition process, an ion-implantation process, or a high temperature annealing process.

12. The overlay control method of claim 11, wherein the process condition corrects an error occurring when the first pattern is transferred to the first layer of the substrate.

13. A semiconductor manufacturing method, comprising:
transferring, by first lithography equipment, a first pattern onto a first layer of a semiconductor wafer;
measuring, by the first lithography equipment, an alignment error between the first pattern of the first layer and a second pattern of a second layer of the semiconductor wafer, wherein the second layer is a lower layer of the semiconductor wafer relative to the first layer;
determining whether the alignment error is correctable by the first lithography equipment; and
providing feedback information to second lithography equipment when the alignment error is not correctable by the first lithography equipment, wherein the second lithography equipment transferred the second pattern on the second layer of the semiconductor wafer.

14. The semiconductor manufacturing method of claim 13, wherein the determining whether the alignment error is correctable comprises:
determining a process condition of a lithography process executed by the first lithography equipment which corrects the alignment error; and
identifying whether the process condition is within a specified range associated with the first lithography equipment, wherein the specified range indicates an extent to which the first lithography equipment can operate.

15. The semiconductor manufacturing method of claim 13, further comprising, when the error is correctable:
determining a process condition of a lithography process executed by the first lithography equipment which corrects the alignment error; and
executing, by the first lithography process, the lithography process in accordance with the process condition.

16. The semiconductor manufacturing method of claim 13, wherein the feedback information includes information on the alignment error and information regarding a tolerance of the first lithography equipment indicating an extent of errors correctable by the first lithography equipment.

17. The semiconductor manufacturing method of claim 13, wherein the first lithography equipment is at least one of extreme ultraviolet lithography equipment or nanoimprint lithography equipment.

18. The semiconductor manufacturing method of claim 13, further comprising:
determining a process condition of a lithography process executed by the second lithography equipment configured to transfer the second pattern to the second layer of the semiconductor wafer, wherein the process condition pre-corrects the alignment error; and
executing, by the second lithography process, the lithography process in accordance with the process condition.

19. The semiconductor manufacturing method of claim 18, wherein the executing the lithography process comprises executing the lithography process on a subsequent wafer lot.

20. A semiconductor manufacturing apparatus, comprising:
means for transferring a pattern to a layer of a semiconductor wafer in accordance with a set of process conditions;
means for measuring an alignment between the pattern transferred to the layer and a previous pattern transferred to a previous layer of the semiconductor wafer; and
means for adjusting the set of process conditions based upon the alignment between the pattern and the previous pattern and feedback information, from a previous wafer lot, obtained from another semiconductor manufacturing apparatus associated with a later process step of a semiconductor manufacturing process.
